(19) United States
(12) Patent Application Publication
(10) Pub. No.: US 2009/0016853 A1
(43) Pub. Date: Jan. 15, 2009

(54) IN-LINE WAFER ROBOTIC PROCESSING SYSTEM

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/775,075

(22) Filed: Jul. 9, 2007

(51) Int. Cl. H01L 21/677

(52) U.S. Cl. 414/147; 414/217.1; 414/805; 901/15

(57) ABSTRACT

A system for processing semiconductor wafers, includes a plurality of front opening unified pods (FOUPs), loadlocks for receiving the plurality of wafers, a plurality of process chambers configured to perform processing steps and or measurement steps on the wafers, loadlock cooling stations for receiving the wafers from the processing chambers and a transport chamber interconnecting the loadlocks, cooling chambers and process chambers. A first multi-axis robot transfers wafers between the FOUPs, loadlocks and loadlock cooling stations, at an ambient pressure. A second multi-axis robot tranfers wafers between the loadlocks, process chambers and the loadlock cooling stations, and is adapted to operate in a transport chamber at a pressure that is different from the ambient pressure.

### BACKGROUND

1. Field of Invention

This invention generally relates to semiconductor manufacturing methods and, more particularly, to systems and methods for wafer processing using multiple process chambers accessed through a plurality of load locks and cooling chambers by multiple robots.

2. Related Art

In the semiconductor industry, to continue to make advancements in the development of semiconductor devices, especially semiconductor devices of decreased dimensions, new processing and manufacturing techniques have been developed.

The semiconductor industry continues a predictable trend toward higher densities of the features within integrated circuits. From the 10-micron range in 1970, feature dimensions of 0.13 microns to 65 mn are now common. These extremely high densities have driven the need for extremely clean processes within semiconductor fabrication facilities. The concern for contamination has been one force driving the automation of processes and the removal of human operators from the processing area.

As the features within devices have become smaller, the devices themselves have grown larger to accommodate greater functional complexity. With that has come a growth in the size of wafers. Larger wafers allow for more devices with a smaller percentage of devices being lost at the circumference of the wafer. As more devices are produced with fewer wafers being handled, the manufacturing cost of each device can be reduced.

The first robots for handling 300-mm wafers were introduced about 1998. Transport carriers containing 25 300-mm wafers are now common. This means that a full carrier may weigh more than humans can carry safely and reliably in transfers between process stations. Considering that a single finished wafer may have value exceeding $100,000, extreme care is required in the handling of wafers to avoid damage. This justifies the need for robotic assistance, which can repeat handling operations with precision and without fatigue, where a single wafer carrier may contain product valued in millions of dollars.

Given these and other considerations, a high level of automation is increasingly employed for handling semiconductor wafers during fabrication. The processing environment is commonly arranged as a wafer transfer system (WTS) that supplies wafers to a process section, which may have its own separate process automation and wafer handling. The WTS may commonly be contained in a clean room where stringent particulate filtration and humidity control is maintained at considerable expense.

As the semiconductor industry has developed into a commodity market with high volumes and low margins, it has become extremely important to create and adopt standards wherever possible. One such standard, developed specifically for use with 300-mm wafers, is a transport carrier and storage device known as a Front Opening Unified Pod, or FOUP. Containing as many as twenty-five 300-mm wafers, a FOUP is a sealed case with a locked panel. The panel may be removed manually or by automation at the WTS for extraction of the wafers while supporting the wafers in an ultra clean environment.

Controlling the ambient environment and automated handling of semiconductor wafers continuously between process steps, during process steps, and during transfers between process steps would be advantageous in reducing contamination exposure, handling, total processing time, and power consumption. A loadlock may typically be used to introduce or remove semiconductor wafers into or from a controlled environment held continuously at, for example, reduced pressure, even high vacuum. Loadlock systems are ambient atmosphere-to-vacuum (or, alternatively, ambient atmosphere-to-higher pressure) sample staging and entry systems typically mounted to larger research or process systems. They may require a convenient and practical method for transferring samples in and out of vacuum systems.

Because of the high capital cost associated with a wafer fabrication facility, two other considerations come into play. One is the cost per square foot, particularly of the floor space within clean rooms. The other is the productivity of that floor space. Productivity alone is usually measured as throughput in units of wafers per hour (wph), while together the two issues can be quantified as wafers per hour per square-meter. Typically, semiconductor device manufacturers may seek to avoid increases in equipment footprint unless there is at least a proportional increase in wafer processing throughput.

One such processing technique is known as Rapid Thermal Processing (RTP), which reduces the amount of time that a semiconductor device is exposed to high temperatures during processing. The RTP technique, described in U.S. Pat. No. 6,303,906, may typically include irradiating the semiconductor device or wafer with sufficient power to quickly raise the temperature of the wafer and hold it at that temperature for a time long enough to successfully perform a fabrication process, but which avoids such problems as unwanted dopant diffusion that would otherwise occur at high processing temperatures over extended time. Wafers may be loaded from a FOUP or other wafer handling module.

In another processing system, one or more wafers may be heated in an annealing process chamber, singly or in a stacked arrangement in an annealing oven, in which defects that may arise in one or more semiconductor processes may annealed thermally. Single and stacked annealing ovens (SAOs) are described in U.S. Pat. No. 6,345,150. Wafers may be loaded from a FOUP or other wafer handling module.

Additional processes, such as characterization monitoring and measurement, may be used during and/or between various fabrication processing steps. A dynamic wafer stress management system is described in commonly-owned U.S. patent application Ser. No. 11/625,778, and is representative of one of numerous characterization systems that may be employed.

Unfortunately, an integrated processing environment in which the environment is completely controlled, for example, from the transfer of wafers from a FOUP, to a loadlock chamber, to one or more process and characterization chambers, such as a rapid thermal processing furnace or a stacked wafer annealing oven, characterization chambers, cooling stations, and finally returned to a FOUP at ambient clean room pressure from vacuum or other pressure is not readily available to meet the needs of RTP or SAO in a continuous processing operation. Robotic handling may currently be limited to transfer handling between only two particular stations, which may result in considerable duplication, footprint increase, and cost to automate each step of handling and processing. Transfers between wafer storage/handling systems, such as FOUPs and loadlocks may currently be manual, which may result in additional contamination concerns due to human presence in the fabrication process. Furthermore, current systems may require clean room floor space that results in increased cost in terms of throughput per square-meter of floor space.

Therefore, there is a need to structure and cluster semiconductor wafer processing tools and systems in a wafer transfer system to enable efficient use of clean room space, and enhance wafer throughput and production efficiency.

### SUMMARY

In one embodiment of the present disclosure, a system for processing semiconductor wafers includes a plurality of front opening unified pods (FOUPs) configured to supply and/or receive a plurality of wafers, a plurality of loadlocks for receiving the plurality of wafers, wherein the loadlocks are configured with a plurality of gates and valves for access to pumps to change the pressure of the loadlocks. A first multi-axis robot arm is positioned to transfer wafers between the front opening unified pods, loadlocks, and loadlock cooling stations, and is adapted to operate at an ambient atmospheric pressure. A plurality of process chambers are configured to perform associated processing steps on the wafers. A plurality of loadlock cooling stations are configured to receive the plurality of processed wafers, wherein the cooling stations comprise a loadlock configured with a plurality of vacuum gates, and valves for access to pumps to change the pressure of the loadlock. A second multi-axis robot positioned between the loadlocks, the loadlock cooling stations, and the process chambers is adapted to operate in a transport chamber at a pressure that is different from the ambient pressure. The transport chamber, configured with a plurality of vacuum gates, and valves for access to pumps to change the pressure of the transport chamber, is positioned between the plurality of loadlocks, loadlock cooling stations, and the plurality of process chambers, and contains the second robot to provide wafer transfer between the loadlocks and the process chambers, and between the process chambers and the loadlocks cooling stations.

In another embodiment of the present disclosure, a method of processing wafers includes providing a plurality of wafers in a one or more front opening unified pods (FOUPs) at an ambient pressure. The wafers from the FOUPS are placed in one of a plurality of loadlock chambers using a first robot arm. Using a second robot arm in a transport chamber, the wafers are transferred from one of the loadlock chambers to one or more process chambers in succession though a transport chamber that is at a pressure different than the ambient pressure. A process associated with each of the process chambers is performed on the one or more wafers. The wafers are moved from the succession of process chambers to one of the loadlock cooling stations using the second robot arm. The wafers are removed from the loadlock cooling station to one of the plurality of FOUPs using the first robot arm operating at ambient pressure.

These and other features and advantages of the present invention will be more readily apparent from the detailed description of the preferred embodiments set forth below taken in conjunction with the accompanying drawings.

### BRIEF DESCRIPTION OF THE DRAWINGS

FIG. 1A is a top view of an in-line single wafer robotic rapid thermal processing furnace system, according to one embodiment of the disclosure.

FIG. 1B is a side view of the in-line single wafer robotic rapid thermal processing furnace system of FIG. 1A.

FIG. 2A is a top view of a robotic in-line single wafer annealing oven processing system, according to one embodiment of the disclosure.

FIG. 2B is a side view of the robotic in-line single wafer annealing oven processing system of FIG. 2A.

FIG. 3 is a top view of a robotic in-line processing system including more than one process chamber type, according to one embodiment of the disclosure.

FIG. 4 is a top view of a robotic in-line processing system including a monitoring/characterization chamber, according to another embodiment of the disclosure.

FIG. 5 is a side view of a portion of the processing system of FIG. 4.

FIG. 6 is a side view of a portion of the processing system of FIG. 4, showing further details of the surface profile characterization system.

Embodiments of the present invention and their advantages are best understood by referring to the detailed description that follows. It should be appreciated that like reference numerals are used to identify like elements illustrated in one or more of the figures.

### DETAILED DESCRIPTION

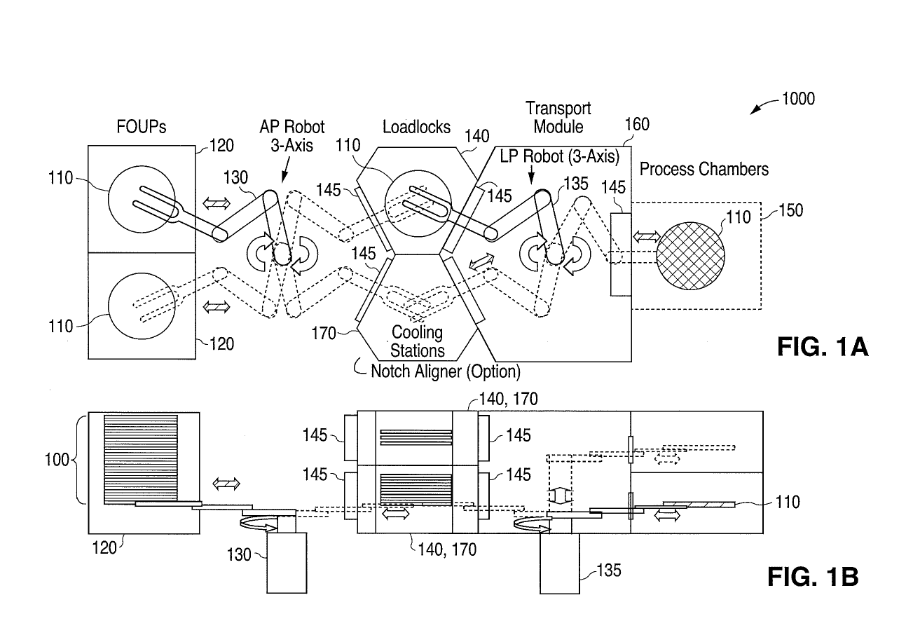

FIG. 1A is a top view of an in-line single wafer robotic rapid thermal processing furnace system 1000, according to one embodiment of the disclosure. FIG. 1B is a side view of the in-line single wafer robotic rapid thermal processing furnace system 1000, as shown in FIG. 1A. In the embodiment shown in FIGS. 1A and 1B, it is noted that various modules may be positioned vertically as well as horizontally, thereby reducing the footprint of system 1000.

System 1000 may operate entirely within a clean room, where environmental characteristics including at least particulate filtration, temperature, and humidity are controlled. Vertically stacked sets 100 of horizontally oriented wafers 110 may be obtained from or returned to one or more vertically and/or horizontally positioned front opening unified pods (FOUPs) 120 by a clean room ambient pressure (AP) robot arm 130. The stacking of sets 100 and orientation of wafers 110 is exemplary, and not limiting in accordance with the disclosure. AP Robot 130 may be, for example, a 3-axis robot, or a Selective Compliant Articulated Robot Arm (SCARA) type robot. AP Robot 130 may be additionally equipped with a wrist rotation fourth degree of freedom, which may enable re-orientation of a wafer or wafer carrier between a horizontal and a vertical orientation.

Load lock stations 140 may receive one or more sets 100 or individual wafers 110 in a plurality of stacked carriers for transfer of wafers 110 from ambient pressure to a process chamber such as, for example, a single wafer rapid thermal furnace 150, or a stacked annealing oven (not shown). Each load lock station 140 may be equipped with two sealing gates 145, such as dual O-ring vacuum gates that are well known in the art, to enable the transition from clean room ambient pressure to a different pressure of a transport module (TM) 160 in order to transfer wafers to the process chamber 150 without having to cycle the pressure of process chamber 150 or TM 160.

TM 160 may interface each of adjoining loadlocks 140 and process chamber 150 with sealing gates 145, and one or more cooling stations 170, where wafers may be transported to cooling stations 170 after processing in process chamber 150. Cooling station 170 may be a loadlock comprising cooling platens (not shown) to lower the temperature of wafers 110 that have been processed in process chamber 150, and which may have been at an elevated temperature as a result of processing. Cooling station 170 may further comprise a notch aligner (not shown) for orienting wafers 110 for subsequent process steps at another process system location, including another process chamber. Loadlocks 140, process chambers 150, TM 160, and cooling stations 170 may all be configured with valves and pumps to permit changing or maintaining selected pressure levels independently.

The positioning of loadlocks 140 and loadlock cooling stations 170, as shown in FIG. 1A is merely exemplary. Alternatively, loadlocks 140 and loadlock cooling stations 170 may be positioned in stacked arrangements, one above another, side-by-side, and at different locations around TM 160, as may be required by various possible arrangements of process chambers 150.

A second robot, LP robot 135, which may be adapted to operate at a lower and/or higher pressure than clean room ambient, in TM 160 may move wafers 110 from loadlocks 140 to process chamber 150 and from process chamber 150 to cooling stations 170. Both TM 160 and process chamber 150 may be maintained continuously at a substantially same pressure during wafer transfer or between wafer transfer transactions, whereby the need to cycle pressure and purge gases between transfers may be eliminated or reduced. Thus, an increase in wafer transfer rate and processing throughput may be achieved. Second LP robot 135 may have substantially the same features and configuration as robot 130, i.e., a 3-axis robot, or a Selective Compliant Articulated Robot Arm (SCARA) type robot, and additionally may be adapted to operate in a pressure environment of TM 160, which may be lower or higher than clean room ambient pressure. Both robots 130 and 135 may be adapted to execute both snake-like articulation and radial motion. Snake-like motion of the articulating robot joints provides linear trajectories capable of removing and inserting wafers in the various modules (i.e., loadlocks 140, cooling stations 145, and process chambers 150). Radial (i.e., angular rotation) motion about the vertical axis provides rotational motion in order to present wafers 110 at the various modules, which may be arranged in an approximately circular fashion about the central axis of LP robot 135. Vertical or Z-type motion of robots 130 and 135 enable transferring wafers to various chambers, loadlocks, cooling chambers, etc., arranged at different heights.

After completion of a process in chamber 150, which may be, for example, a single wafer rapid thermal furnace, robot 135 may retrieve wafer 110 and transfer it to cooling station 170. To enable the transfer, the pressure in process chamber 150, TM 160, and cooling station 170 may be substantially equalized (equilibrated) and may, for example, comprise only purging with inert gases to maintain a uniformity of pressure, i.e., there may be maintained substantially no pressure differential between the two. As indicated above, cooling station 170 may be interfaced with TM 160 via a sealing gate 145. Wafer 110 may be transferred by robot 135 from process chamber 150 to cooling station 170 in a single transaction without pressure cycling, thus speeding up the transfer process. Cooling station 170, for example, may be provided with water cooled platens (not shown) or circulating gas to lower the temperature of wafers 110 processed in process chamber 150, which may be a form of oven (e.g., a single wafer rapid thermal furnace) at elevated temperature. Cooling station 170 may optionally include a notch aligner (not shown) to provide a predetermined orientation of each wafer 110 for subsequent processes dependent on wafer orientation.

Since the volume of loadlocks 140 and cooling stations 170 may be smaller than transport chamber 160 and/or process chamber 150, and sets 100 of multiple wafers 110 may be stacked in slots in each of loadlocks 140 and cooling station 170, sets 100 or batches of wafers 110 may be obtained from and returned to a plurality of FOUPs 120 at clean room ambient pressure more quickly and efficiently than may be required if wafers 110 are transferred directly from TM 160 or process chambers 150, thus also reducing the handling of individual wafers 110.

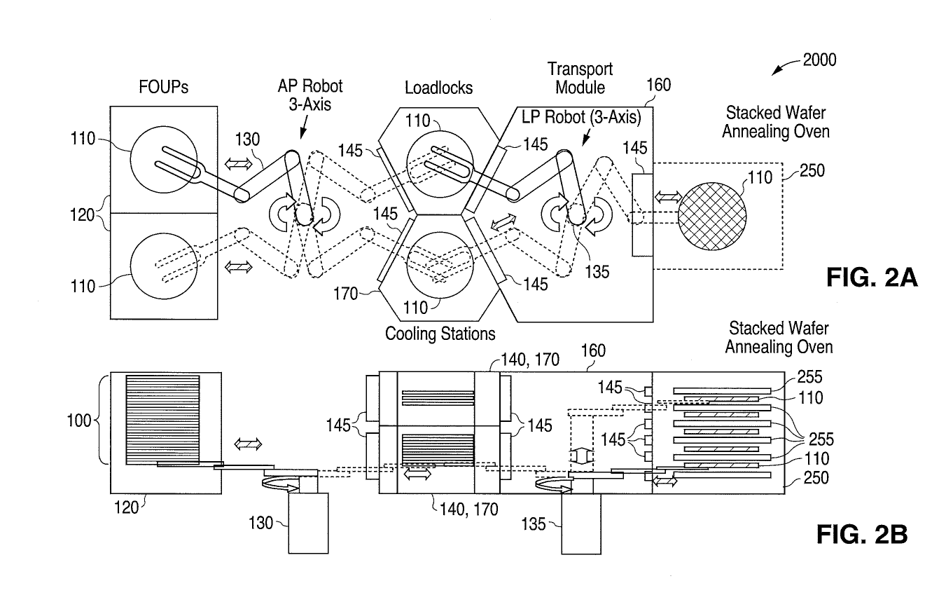

FIG. 2A is a top view of a robotic in-line single wafer annealing oven processing system 2000, according to another embodiment of the disclosure. FIG. 2B is a side view of the robotic in-line single wafer annealing oven processing system 2000, as shown in FIG. 2A. System 2000 may be configured in a manner similar to system 1000, except that the process chamber may be configured for a different process or structure, such as, for example, a stacked wafer annealing oven 250. In stacked wafer annealing oven 250, wafers are placed by robot 135 on individual heating platens 255.

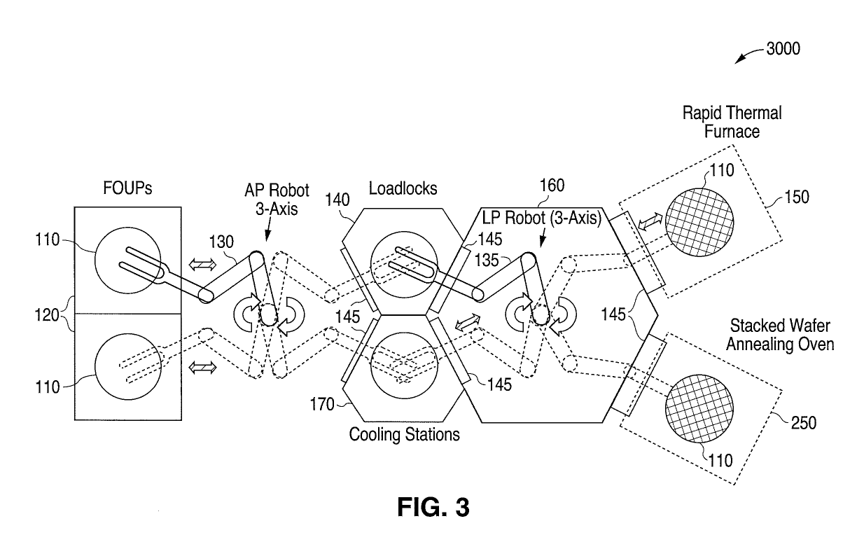

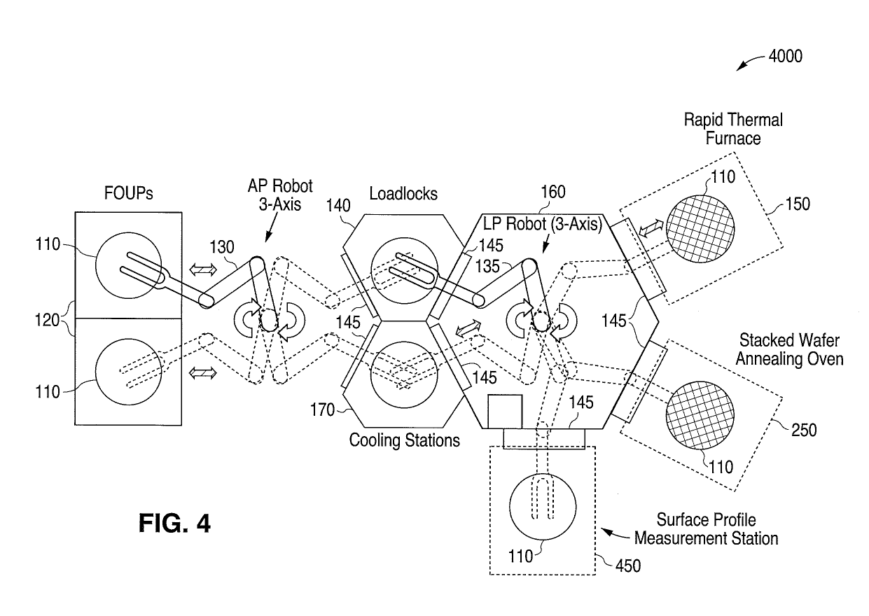

FIG. 3 is atop view of a robotic in-line processing system 3000, according to another embodiment of the disclosure. Processing system 3000 may be generally configured in a manner similar to systems 1000 and 2000, except that a plurality of process chambers, for the same or different processes, may be interfaced with a transport module (TM) 160, where TM 160 is adapted to accommodate a plurality of process chambers with associated gates 145. For example, system 3000 may be configured with single wafer rapid thermal process furnace 150 at one gate and stacked wafer annealing oven 250 at another gate. FIG. 4 is a top view of a robotic in-line processing system 4000 including a monitoring/characterization chamber 450, according to another embodiment of the disclosure. Processing system 4000 may be generally configured in a manner similar to systems 1000, 2000, and 3000, except that one or more monitoring/characterization chambers 450 may be interfaced with transport module (TM) 160, where TM 160 is adapted to accommodate a plurality of process chambers with associated gates 145. For example, system 4000 may be configured with a wafer stress measurement system 450, described in U.S. patent application Ser. No. 11/625,778, “Dynamic Wafer Stress Management System,” filed Jan. 22, 2007, which is a continuation-in-part of U.S. patent application Ser. No. 11/291,246, entitled “Optical Sample Characterization System”, filed on Nov. 30, 2005, now Pub. No. 20070121105, both of which are incorporated by reference herein in their entirety. Therefore, it will not be described in full detail, except as follows.

Before, after, and between process steps wherein wafers 110 undergo processes that may result in mechanical stress, such as heating in a rapid thermal processing oven or an annealing oven, or due to deposition of materials that may have thermo-mechanical expansion properties that differ from wafers 110, a characterization process may be desirable to measure changes in wafers 110, such as stress. Stress may lead to warping, such as bowing of wafer, or localized distortion. If the wafer is acceptable, the wafer may be transported back to loadlocks 140 or cooling stations 170 via TM 160. However, if the wafer requires additional processing, processing parameters may be changed and the wafer transferred back to a processing chamber (e.g., 150 or 250) for further processing and re-characterization thereafter if desired.

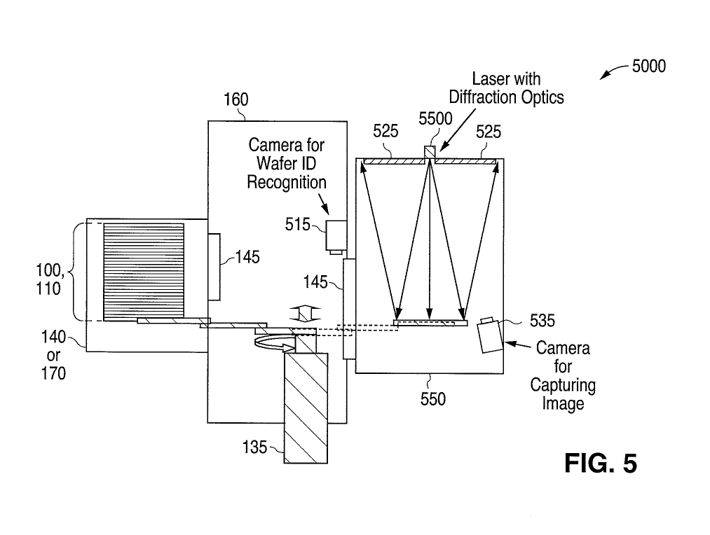

FIG. 5 is a side view of a portion 5000 of processing system 4000, according to the embodiment shown in FIG. 4. Robot LP 135 in transport module TM 160 may obtain wafers from, for example, loadlock 140, prior to thermal or material processes that may occur, and place a single wafer 110 in a characterization chamber 550 such as, for example, a surface profile measurement system. Access by LP robot 135 to any chamber may be through gates 145, so that different or substantially same pressures or gases may be maintained or changed in the various chambers, as needed. A characterization step may take place to obtain a reference measurement of wafer 110 for comparison after a process step.

Wafer 110 may then be transported to one or more process chambers 150 and/or 250 (shown in FIG. 4). After one or more such steps, wafer 110 may be transported by LP robot 135 to characterization chamber 550. A camera 535 placed in relation to chamber 550 may obtain an image of wafer 110, which may be marked with an identification pattern to enable tracking of wafer 110 through the various fabrication processes, and the identifying information stored in a computer system (not shown) which tracks the status of wafers 110. After the characterization step, wafer 110 may be transported to another process chamber or to cooling station 170, for eventual removal by AP robot 135 and placement in one of several accessible FOUPs 120.

In the embodiment shown in FIG. 5, characterization chamber 550 includes a laser system 5500 comprising focusing and diffraction optics (discussed below). Chamber 550 may be equipped with a window (not shown) transparent to the wavelength of light produced by laser system 5500. Laser system 5500 produces a pattern of illumination which is projected on wafer 110. The pattern may be reflected from wafer 110 to a screen 525 which may, for example, be placed surrounding the window which admits the light pattern provided by laser system 5500. Camera 535 obtains the image projected on screen 525. The image may correspond to, for example, wafer warp before or after various process steps.

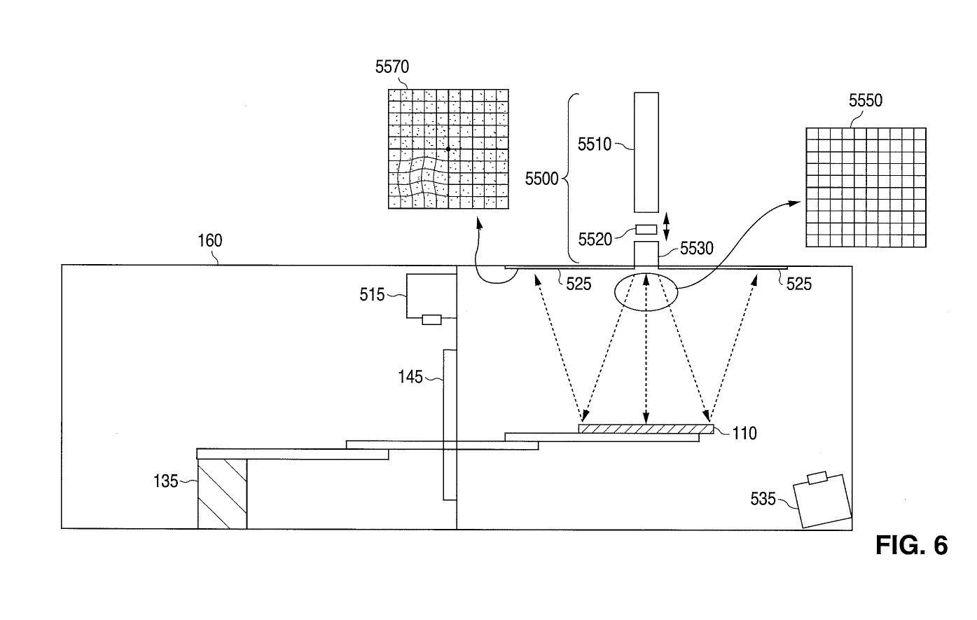

FIG. 6 is a side view of a portion of processing system 4000, showing further details of the surface profile characterization system. The embodiment is exemplary, and various other measurement and characterization systems and methods may be implemented within the spirit of the disclosure. Laser system 5500 may comprise a laser 5510, beam optics 5520 to shape or expand the laser beam for illumination of a mask 5530, which contains a grid pattern 5550. Laser system 5500 projects grid pattern 5550 onto wafer 110. The reflected image may appear on screen 525 as a grid pattern 5570 with distortions in the grid relative to that of pattern 5550 resulting from distortions of wafer 110. Images of grid pattern 5570, before and after one or more material and thermal processes to which wafer 110 has been subjected to, may be compared using image signal processing algorithms implemented on a computer (not shown) to determine stress in wafer 110 caused by the processes.

Process chambers 150, 250, 550, etc. are not limited to the examples indicated above. A large number of processes, including inspection and characterization, may be included in the one or more process chambers of the systems contemplated. These process chambers include, but are not limited to, rapid thermal processing furnace, annealing oven, ashing oven, oxidation furnace, diffusion furnace, chemical vapor deposition furnace, sputtering chamber, plasma vapor deposition furnace, etching chamber, plasma enhanced chemical vapor deposition chamber, atomic layer deposition, atomic layer epitaxy (ALE), atomic layer deposition (ALD), molecular beam epitaxy (MBE), chemical beam epitaxy (CBD), chemical beam epitaxy deposition (CBD), plasma reaction deposition, thermal evaporation, electron-beam evaporation, electroplating, liquid phase epitaxy (LPE), molecular beam epitaxy (MBE) (e.g., metal-organic), chemical vapor deposition (CVD), solid phase epitaxy (SPE), cleaning chamber, inspection chamber, material characterization chamber and related combinations of these processes. Furthermore, various inspection and/or characterization processes may be simultaneously included in one or more of the various fabrication process chambers for simultaneous monitoring and control of the processes.

Various benefits may be realized with systems as described above. For example, the clustering of wafer storage chambers (such as FOUPs), and process systems around a centralized robot makes for efficient utilization of space, and lower contamination levels due to the reduced presence of humans in the clean room environments. Incorporating robotic wafer handling in controlled pressure transport chambers and clustering processing, inspection and characterization chambers around the centralized transport chamber further reduces human interference, and may greatly reduce the footprint and energy requirements to perform a succession of fabrication and measurement processes on individual and batches of wafers.

It will thus be obvious to those skilled in the art that various changes and modifications may be made without departing from this invention in its broader aspects. Various embodiments show multiple FOUPs, process chambers, loadlocks, and/or cooling stations. However, single ones of these in various combinations are also suitable. Therefore, the appended claims encompass all such changes and modifications as fall within the true spirit and scope of this invention.

What is claimed is:

1. A system for processing semiconductor wafers, comprising:
a front opening unified pod configured to supply and/or receive a wafer;
a loadlock for receiving the wafer, wherein the loadlock is configured with a plurality of sealing gates;
a process chamber configured to perform processing steps on the wafer;
a cooling station for receiving the processed wafer from the process chamber, wherein the cooling station comprises a loadlock configured with a plurality of sealing gates;
a first multi-axis robot wafer handler between the front opening unified pod and the loadlock and the cooling station, wherein the first wafer handler is adapted to operate at a first ambient pressure;
a second multi-axis robot between the loadlock and the cooling station and the process chamber, wherein the second wafer handler is adapted to operate at a second pressure that is different from the first ambient pressure; and
a transport chamber configured to contain the second wafer handler, wherein the second wafer handler is adapted to transfer the wafer between the load lock and the process chamber and between the process chamber and the cooling station.

2. The system of claim 1, wherein the first wafer handler comprises a 3-axis robot, a selective compliant articulated robot arm, or a 4 degree-of-freedom robot arm with a 3-axis motion and a wrist rotation.

3. The system of claim 1, wherein the front opening unified pod comprises a carrier adapted to hold the wafers.

4. The system of claim 1, wherein the loadlock and the cooling station are configured with seal gates and adapted to pump to a pressure different from an ambient pressure.

5. The system of claim 1, wherein the second wafer handler comprises a 3-axis robot, a selective compliant articulated robot arm, or a 4 degree of freedom robot arm with a 3-axis motion and a wrist rotation.

6. The system of claim 1, wherein the second wafer handler is adapted to operate at a pressure different from an ambient pressure.

7. The system of claim 1, wherein the transport chamber is adapted to operate at a pressure different from an ambient pressure.

8. The system of claim 1, where the process chamber comprises a rapid thermal processing (RTP) furnace, lamp-based radiation heating chamber, annealing oven, ashing oven, oxidation furnace, diffusion furnace, chemical vapor deposition furnace, sputtering chamber, physical vapor deposition (PVD) chamber, etching chamber, plasma enhanced chemical vapor deposition (PECVD) chamber, atomic layer deposition, atomic layer epitaxy (ALE), atomic layer deposition (ALD), molecular beam epitaxy (MBE), chemical beam epitaxy (CBE), chemical beam epitaxy deposition (CBD), plasma reaction deposition, plasma doping, flash anneal, laser processing, thermal evaporation, electron-beam evaporation, electroplating, liquid phase epitaxy (LPE), molecular beam epitaxy (MBE) (e.g., metal-organic), chemical vapor deposition (CVD), solid phase epitaxy (SPE), cleaning chamber, inspection chamber, material characterization chamber and related combinations of these processes.

9. The system of claim 1, further comprising a plurality of front opening unified pods.

10. The system of claim 1, further comprising a plurality of process chambers.

11. The system of claim 10, where the plurality of process chambers comprise one or more characterization and/or process monitoring systems.

12. The system of claim 1, where the process chambers are configured with sealing gates and adapted for operation at a pressure different from an ambient pressure.

13. The system of claim 1, wherein the cooling station comprises a notch aligner.

14. The system of claim 1, wherein the transport chamber and the second wafer handler are adapted to operate at a pressure different than the first ambient pressure.

15. The system of claim 1, wherein the process chambers are stacked vertically to interface with the transport chamber.

16. The system of claim 1, wherein the process chambers are arranged horizontally to interface with the transport chamber.

17. The system of claim 1, wherein the loadlocks and loadlock cooling stations are stacked vertically or horizontally to interface with the transport chamber.

18. A method of processing wafers, comprising:
providing a wafer in a one or more front opening unified pods (FOUPs) at an ambient pressure;
placing the wafer in a loadlock chamber using a first robot arm;
transferring the wafer through a transport chamber to successively one or more process chambers using a second robot arm at a pressure that is the same or different than the ambient pressure;
performing a process associated with the one or more process chambers;
moving the wafer to a loadlock cooling station using the second robot arm; and
moving the wafer to the one of the FOUPs using the first robot arm.

19. The method of claim 18, further comprising:
closing a first gate of the loadlock after the wafer is positioned;
changing the pressure of the loadlock to a predetermined pressure of the transport chamber; and
opening a second gate of the loadlock interfaced to the transport chamber when the predetermined pressure is obtained.

20. The method of claim 18, further comprising:
equilibrating the pressure between the transport chamber and the process chamber; and
delivering the wafer from the loadlock through a gate of the process chamber using the second robot arm in the transport chamber, wherein the transport chamber is at the same pressure as the process chamber.

21. The method of claim 18, wherein the performing comprises:
processing the wafer;
measuring the wafer in a different chamber; and
repeating the processing and measuring as needed before moving the wafer to the loadlock.

22. The method of claim 18, further comprising:
opening a gate interfaced between the process chamber and the transport chamber, wherein the transport chamber is at the same pressure as the process chamber;
retrieving the wafer from the chamber using the second robot if the moving is after the performing of the process;
opening the gate interfaced between the transport chamber and the loadlock cooling station, wherein the loadlock cooling station is at the same pressure as the transport chamber;
transferring the wafer from the process chamber using the second robot arm to the loadlock cooling station; and
closing the gate interfaced between the transport chamber and the loadlock cooling station.

23. The method of claim 18, wherein further comprising:
equilibrating the pressure in the loadlock cooling chamber to the ambient pressure;
opening a gate interfaced between the loadlock cooling chamber and the ambient pressure;
removing the wafer from the loadlock cooling station using the first robot arm and placing the wafer in the FOUP.
